(19) United States
(12) Patent Application Publication
(10) Pub. No.: US 2013/0265716 A1
(43) Pub. Date: Oct. 10, 2013

(54) CHASSIS STRUCTURE FOR MOUNTING EXPANSION CARDS

(71) Applicants: HONG FU JIN PRECISION INDUSTRY (ShenZhen) CO., LTD., (US); HON HAI PRECISION INDUSTRY CO., LTD., New Taipei (TW)

(72) Inventor: LEI LIU, Shenzhen (CN)

(73) Assignees: HON HAI PRECISION INDUSTRY CO., LTD., New Taipei (TW); HONG FU JIN PRECISION INDUSTRY (ShenZhen) CO., LTD, Shenzhen (CN)

(21) Appl. No.: 13/718,548

(22) Filed: Dec. 18, 2012

(30) Foreign Application Priority Data
Apr. 9, 2012 (CN) 201210100808.8

(51) Int. Cl. G06F 1/18; H05K 5/02

(52) U.S. Cl. CPC G06F 1/181; H05K 5/0286
USPC 361/679.58; 312/223.1

(57) ABSTRACT

A chassis structure includes a support frame defining a plurality of slots parallel to each other. The support frame includes a mounting plate and a locking module. The mounting plate and the locking module are configured for mounting different types of expansion cards.

### BACKGROUND

1. Technical Field

The exemplary disclosure generally relates to chassis structures for mounting expansion cards, and, particularly, to a chassis structure for mounting different types of expansion cards used in a computer/server.

2. Description of Related Art

Expansion cards such as peripheral component interconnect (PCI) cards are widely used in computers or servers. To mount PCI cards to the computers or the servers, each PCI card includes a bracket. However, the bracket usually includes two types: standard bracket and low-profile bracket. The standard bracket is longer than the low-profile bracket. The conventional computer or server only can mount one type of bracket. Users cannot mount different types of PCI cards in the same computer/server. Thus, it can be inconvenient for users.

Therefore, there is room for improvement within the art.

### BRIEF DESCRIPTION OF THE DRAWINGS

Many aspects of the chassis structure for mounting expansion cards can be better understood with reference to the following drawings. The components in the drawings are not necessarily drawn to scale, the emphasis instead being placed upon clearly illustrating the principles of the chassis structure for mounting expansion cards, in which:

FIG. 1 is an exploded, isometric view of a chassis structure for mounting expansion cards, in accordance with a first exemplary embodiment.

FIG. 2 is an assembled view of the chassis structure for mounting expansion cards.

FIG. 3 is an exploded, isometric view of the chassis structure for mounting expansion cards, in accordance with a second exemplary embodiment.

FIG. 4 is an assembled view of the chassis structure for mounting expansion cards.

### DETAILED DESCRIPTION

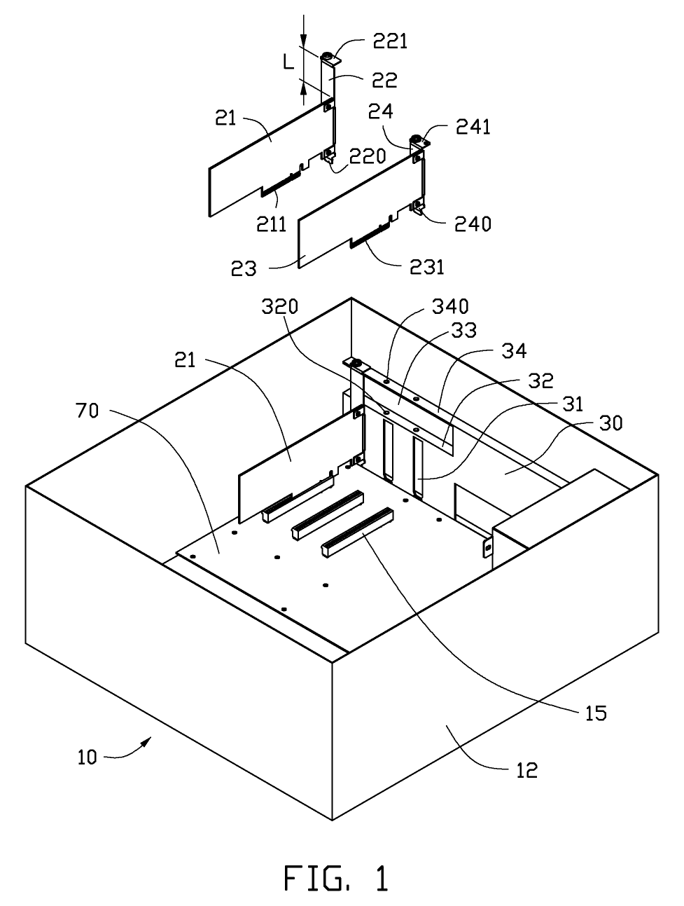

FIG. 1 shows an exemplary embodiment of a chassis structure 10 for mounting different expansion cards applied to a computer. In this exemplary embodiment, at least one first PCI expansion card 21, at least one second PCI expansion card 23, and a motherboard 70 are received in the chassis structure 10. A plurality of expansion sockets 15 are formed on the motherboard 70, for electronically connecting the first PCI expansion cards 21 and the second PCI expansion cards 23.

Each first PCI card 21 includes a first bracket 22 and a first connector 211. The first connector 211 is configured for engaging with one of the expansion sockets 15. The first bracket 22 is positioned at one side of the first PCI card 21 and includes a first end 221 and a second end 220. Each second PCI card 23 includes a second bracket 24 and a second connector 231. The second connector 231 is configured for engaging with one of the expansion sockets 15. The second bracket 24 is positioned at one side of the second PCI expansion card 23 and includes a first end 241 and a second end 240. In this exemplary embodiment, the first bracket 22 is a standard bracket, and the second bracket 24 is a low-profile bracket shorter than the first bracket 22. An “L” is used for representing the length difference between the first bracket 22 and the second bracket 24.

The chassis structure 10 includes a bottom plate 11 and four sidewalls 12 connected to each other. A support frame 30 is mounted on one of the sidewalls 12. The support frame 30 defines a plurality of slots 31 parallel to each other. A groove 33 is recessed on the support frame 30 to form a mounting plate 32 and a locking module. The locking module comprises a positioning plate 34. The mounting plate 32 and the positioning plate 34 are configured for mounting the first brackets 22 and the second brackets 24. In this exemplary embodiment, a distance between the mounting plate 32 and the positioning plate 34 is equal to the length difference L between the first bracket 22 and the second bracket 24. The mounting plate 32 is adjacent to the slots 31 and defines a plurality of first holes 320. The positioning plate 34 defines a plurality of second holes 340.

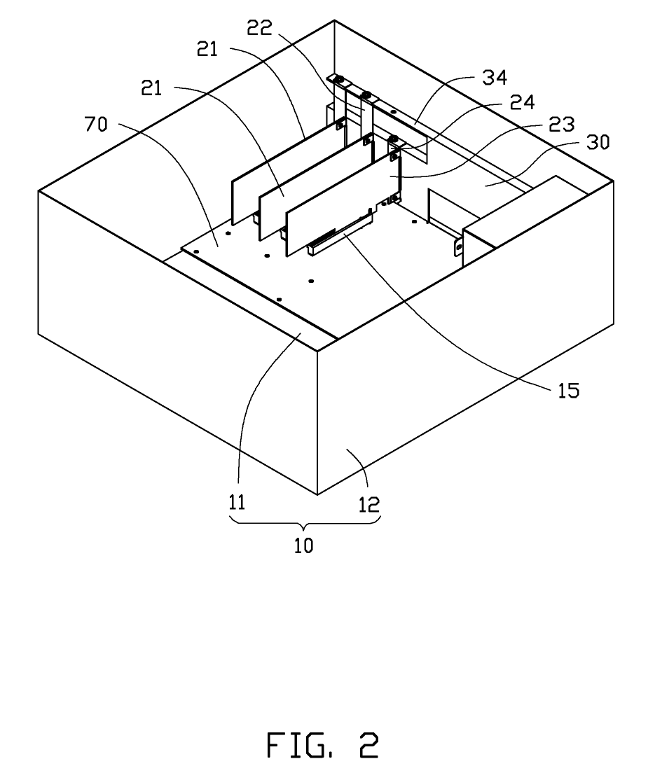

FIG. 2 shows that in assembly, the first connector 211 of the first PCI card 21 is plugged into one of the expansion sockets 15 and one end of the first PCI card 21 is exposed from one of the slots 31. The first end 221 of the first bracket 22 is attached to the positioning plate 34. The first end 221 is mounted in the second hole 340 with screw, the second end 220 of the first bracket 22 is inserted into a clearance between the motherboard 70 and the support frame 30, for mounting the first PCI card 21 on the support frame 30. The second PCI card 23 is aligned with one of the slot 31. The first end 241 of the second bracket 24 is mounted to the first hole 320, of the mounting plate 32, with a screw. Accordingly, the first PCI expansion card 21 and the second PCI expansion card 23 are mounted on the chassis structure 10.

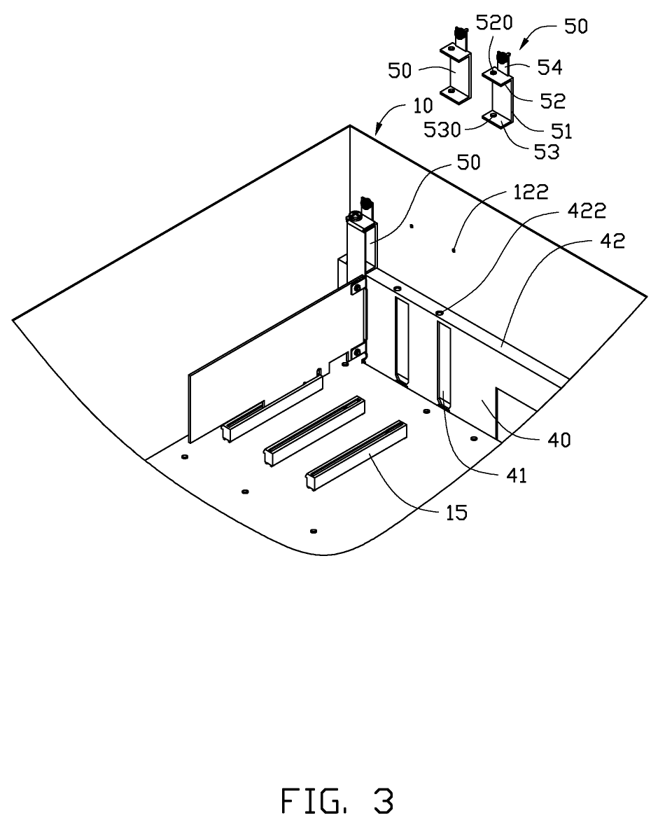

In a second embodiment, referring to FIG. 3, the chassis structure 10 includes a support frame 40 mounted on one of the sidewalls 12. The sidewall 12 defines a hole 122. The support frame 40 defines a plurality of slots 41 that are parallel to each other and includes a mounting plate 42 and a locking module. The locking module is made of a plurality of locking members 50. The mounting plate 42 defines a plurality of holes 422. Each locking member 50 includes a main body 51, a first extending end 52, a second extending end 53 and a mounting end 54. The first extending end 52 and the second extending end 53 are perpendicularly connected to the main body 51. The mounting end 54 is formed on the first extending end 52 configured for mounting the locking member 50 to the sidewall 12 with the support frame 40. The first extending end 52 defines a first aperture 520, and the second extending end 53 defines a second aperture 530. Each locking member 50 is predetermined to mount on the support frame 40 by the mounting end 54 engaged in a corresponding hole 122. The length between the first extending end 52 and the second extending end 53 is substantially equal to the length difference L between the first bracket 22 and the second bracket 24.

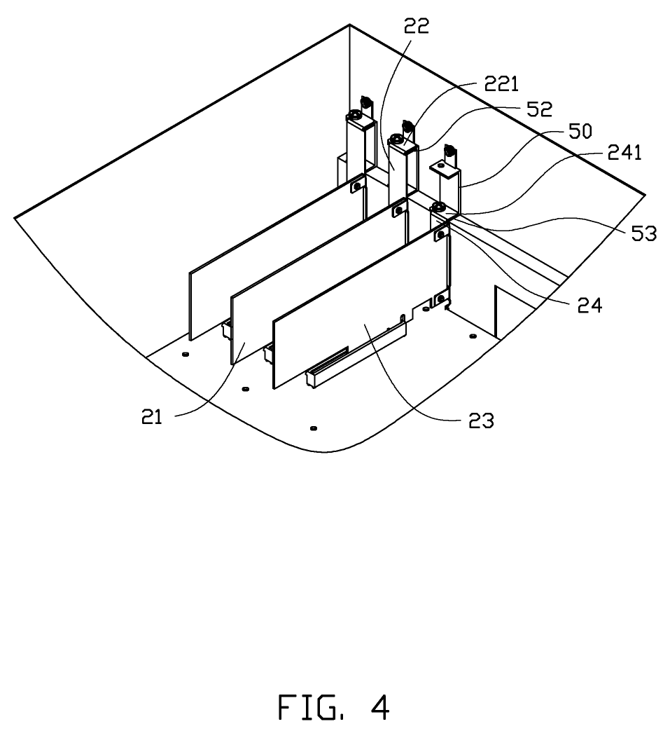

FIG. 4 shows that in assembly, the first connector 211 of the first PCI card 21 is plugged into one of the expansion sockets 15. The first end 221 of the first bracket 22 is attached to the first extending end 52 of the locking member 50. The first end 221 is engaged on the first extending end 52 by screws being mounted into the first aperture 520, the second end 220 of the first bracket 22 is inserted into a clearance between the motherboard 70 and the support frame 30, for mounting the first PCI card 21 on the support frame 30. The first end 241 of the second bracket 24 is placed on the second extending end 53, and the first end 241 and the second extending end 53 are together mounted to the mounting plate 42. Accordingly, the first PCI expansion card 21 and the second PCI expansion card 23 are mounted on the chassis structure 10.

It is to be understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A chassis structure comprising:
a support frame defining a plurality of slots that are parallel to each other, the support frame comprising a mounting plate and a locking module;
wherein the mounting plate and the locking module are configured to mount first expansion cards and second expansion cards, at a different height than the first expansion cards.

2. The chassis structure as claimed in claim 1, wherein the locking module comprises a plurality of locking members, a first end of each locking member is mounted on the mounting plate, and a second end of each locking member is configured for the second expansion cards.

3. The chassis structure as claimed in claim 1, wherein a groove is recessed on the support frame to form the mounting plate and a positioning plate, and the positioning plate forms the locking module.

4. An electronic device comprising:
a computer enclosure with a sidewall; and
a support frame defining a plurality of slots parallel to each other, the support frame comprising a mounting plate and a locking module, the mounting plate and the locking module configured for mounting different types of expansion cards.

5. The electronic device as claimed in claim 4, wherein the locking module comprises a plurality of locking members, a first end of each locking member is mounted on the mounting plate, a second end of each locking member is configured for one type of the expansion cards.

6. The electronic device as claimed in claim 4, wherein a groove is recessed on the support frame to form the mounting plate and a positioning plate, and the positioning plate forms the locking module.
